(19) United States
(12) Patent Application Publication
(10) Pub. No.: US 2011/0263097 A1
(43) Pub. Date: Oct. 27, 2011

(54) METHOD FOR MANUFACTURING SEMICONDUCTOR DEVICE

(76) Inventors: Atsushi YOSHIMURA, Kanagawa-ken (JP); Yasuo TANE, Mie-ken (JP); Yukio KATAMURA, Mie-ken (JP); Fumihiro IWAMI, Kanagawa-ken (JP)

(21) Appl. No.: 13/053,959

(22) Filed: Mar. 22, 2011

(30) Foreign Application Priority Data
Apr. 27, 2010 (JP) 2010-102616

(51) Int. Cl. H01L 21/78

(52) U.S. Cl. 438/463; 257/E21.599

(57) ABSTRACT

According to one embodiment, a method for manufacturing semiconductor device can include forming a groove with a depth shallower than a thickness of a wafer. The method can include attaching a surface protection tape via a first bonding layer provided in the surface protection tape. The method can include grinding a surface of the wafer to divide the wafer into a plurality of semiconductor elements. The method can include forming an element bonding layer by attaching a bonding agent and turning the attached bonding agent into a B-stage state. The method can include attaching a dicing tape via a second bonding layer provided in the dicing tape. The method can include irradiating the first bonding layer with a first active energy ray. The method can include removing the surface protection tape. The method can include irradiating the second bonding layer with a second active energy ray.

### CROSS-REFERENCE TO RELATED APPLICATIONS

This application is based upon and claims the benefit of priority from the prior Japanese Patent Application No. 2010-102616, filed on Apr. 27, 2010; the entire contents of which are incorporated herein by reference.

### FIELD

Embodiments described herein relate generally to a method for manufacturing a semiconductor device.

### BACKGROUND

In a so-called dicing-before-grinding method, a surface protection tape is attached to a surface (a surface in which a circuit pattern is formed) of a wafer, an element bonding layer is formed on the back surface (the surface opposite to the surface in which the circuit pattern is formed) of a fragmentated semiconductor element (a semiconductor chip), and then a dicing tape is attached. Then, when the surface protection tape is removed, the bonding layer formed on the surface protection tape exposed between semiconductor elements is removed along with the surface protection tape.

However, when the surface protection tape is removed, the element bonding layer formed on the surface protection tape may not be removed or the semiconductor element may be removed from the dicing tape, leading to a decrease in productivity.

### BRIEF DESCRIPTION OF THE DRAWINGS

FIGS. 1A and 1C to 1I are schematic cross-sectional views of processes illustrating a method for manufacturing a semiconductor device according to an embodiment, and

FIG. 1B is a schematic enlarged view of a portion A in FIG. 1A.

### DETAILED DESCRIPTION

In general, according to one embodiment, a method is disclosed for manufacturing a semiconductor device. The method can include forming a groove with a depth shallower than a thickness of a wafer from a side of a surface of the wafer in which a circuit pattern is formed. The method can include attaching a surface protection tape to the side of the surface of the wafer in which the circuit pattern is formed via a first bonding layer provided in the surface protection tape and containing a first active energy ray curable resin. The method can include grinding a surface of the wafer on a side opposite to the surface in which the circuit pattern is formed to divide the wafer into a plurality of semiconductor elements. The method can include forming an element bonding layer by attaching a bonding agent to the plurality of semiconductor elements divided and turning the attached bonding agent into a B-stage state. The method can include attaching a dicing tape to a side opposite to surfaces of the plurality of semiconductor elements in which a circuit pattern is formed on which the element bonding layer is formed via a second bonding layer provided in the dicing tape and containing a second active energy ray curable resin. The method can include irradiating the first bonding layer with a first active energy ray. The method can include removing the surface protection tape. In addition, the method can include irradiating the second bonding layer with a second active energy ray having a wavelength different from the first active energy ray.

Embodiments will now be illustrated with reference to the drawings. In the drawings, like components are marked with the same reference numerals and a detailed description thereof is omitted as appropriate.

The manufacturing processes of a semiconductor device include the process of forming a circuit pattern on a surface of a wafer by film-formation, resist application, exposure, development, etching, resist removal, and the like in a so-called pre-process, and the processes of inspection, cleaning, heat treatment, impurity introduction, diffusion, planarization, and the like. A so-called post-process includes the dicing process, the die bonding process, the bonding process, the constituting process such as the sealing process, the inspection process of inspecting functions and reliability, and the like.

In a method for manufacturing a semiconductor device according to the embodiment, the bonding force between a bonding layer provided in a surface protection tape and a semiconductor element, the bonding force between the bonding layer provided in the surface protection tape and an element bonding layer formed on the surface protection tape exposed between semiconductor elements, and the bonding force between a bonding layer provided in a dicing tape and the element bonding layer formed on the back surface of the semiconductor element are controlled in the dicing process or the die bonding process, or between the dicing process and the die bonding process.

Known technology can be applied except controlling these bonding forces, and a description of the processes described above is therefore omitted.

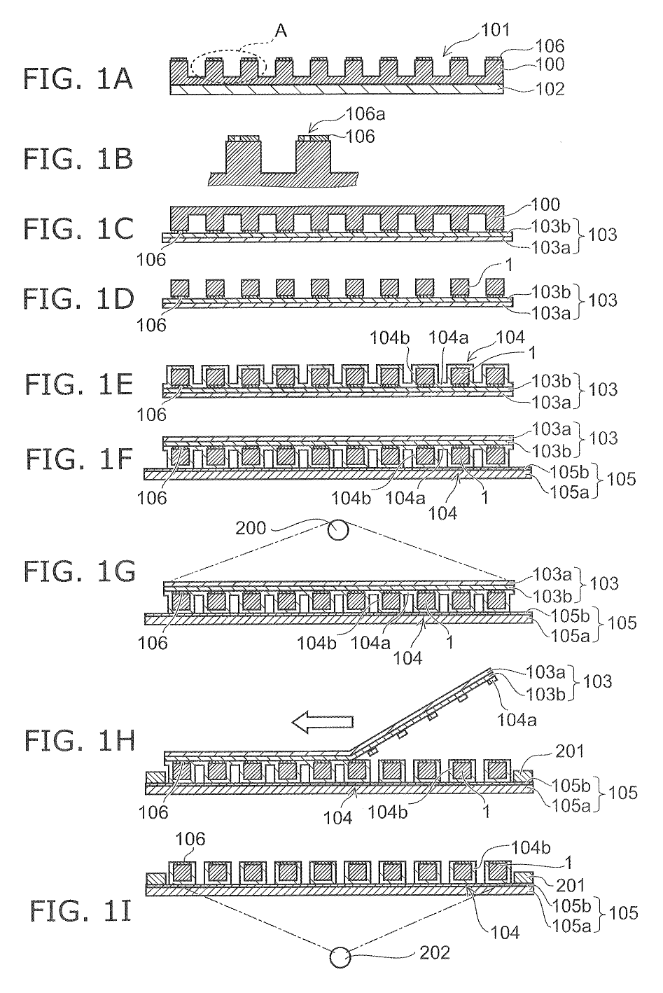

FIGS. 1A to 1I are schematic cross-sectional views of processes illustrating the method for manufacturing a semiconductor device according to the embodiment.

First, as shown in FIG. 1A, grooves 101 with depths shallower than the thickness of a wafer 100 are formed from the side of the front surface (a surface in which a circuit pattern is formed) of the wafer 100. That is, so-called half cut is performed.

In this case, as shown in FIG. 1B, an insulating film 106 is provided on the front surface side of the wafer 100 for protection of the front surface. Therefore, the circuit pattern and the like formed on the front surface side of the wafer do not get damages.

The insulating film 106 is provided with an opening 106a used when electrically connecting (e.g., wire bonding, or the like) to a semiconductor element (a semiconductor chip) in the bonding process.

When the grooves 101 are formed, the back surface (the surface opposite to the surface in which the circuit pattern is formed) of the wafer 100 may be fixed by a fixing tape 102 as necessary.

The blade dicing method, for example, may be used to form the grooves 101. Known technology can be applied to the dicing equipment used for the blade dicing method, the conditions of the dicing, and the like, and a description thereof is therefore omitted. In the case where dicing equipment for halfcut capable of performing halfcut is used in this situation, there is no need to perform the fixing by the fixing tape 102 described above.

The grooves 101 are formed along prescribed cutting positions, and a portion between grooves 101 forms a semiconductor element. The depth of the groove 101 is not specifically limited, and is appropriately set in accordance with the thickness of the semiconductor element.

Next, as shown in FIG. 1C, a surface protection tape 103 is attached to the front surface side of the wafer 100. The surface protection tape 103 is attached so as to cover the entire front surface side of the wafer 100 via a bonding layer 103b (a first bonding layer) that contains an active energy ray curable resin described below (a first active energy ray curable resin).

The laminating method, for example, may be used to attach the surface protection tape 103 to the front surface side of the wafer 100. Then, the back surface of the wafer 100 is turned up to facilitate the grinding of the back surface of the wafer 100. In the case where the fixing by the fixing tape 102 described above has been performed in this situation, the fixing tape 102 is removed. Known technology can be applied to the laminating equipment used for the laminating method, the conditions of the laminating, and the like, and a description thereof is therefore omitted.

The surface protection tape 103 includes a matrix 103a and the bonding layer 103b provided on the matrix 103a.

The material of the matrix 103a may be appropriately selected based on the method for controlling the bonding force of the bonding layer 103b described below. For example, in the case where the bonding layer 103b is formed of an ultraviolet curable resin as described below, the matrix 103a may be made of an ultraviolet transmitting resin so that the irradiation of ultraviolet light (e.g. with a wavelength of 400 nm (nanometers) or less) can be transmitted. In this case, as examples of the ultraviolet transmitting resin, a polyester resin such as polyethylene terephthalate (PET), a polystyrene-based resin, a fluororesin, a polyethylene-based resin, a vinyl resin, and the like can be given.

The bonding layer 103b may be formed of an active energy ray curable resin. The bonding layer 103b formed of an active energy ray curable resin has the properties that it has a prescribed bonding force before being irradiated with an active energy ray having a prescribed wavelength and the bonding force decreases upon irradiation with the active energy ray having a prescribed wavelength in accordance with the irradiation amount.

The type of the active energy ray curable resin is not specifically limited, and may be those containing an active energy ray curable composition, for example.

Here, in the embodiment, the wavelength of the applied active energy ray is set different between the bonding layer 103b and a bonding layer 105b described below. In view of this, an example is herein taken up in which the bonding layer 103b is formed of an ultraviolet curable resin.

The ultraviolet curable resin may contain an ultraviolet curable composition and be cured by a polymerization reaction upon ultraviolet irradiation.

In this case, the ultraviolet curable resin has a prescribed bonding force before being irradiated with ultraviolet light and the bonding force decreases upon ultraviolet irradiation in accordance with the irradiation amount. That is, the bonding force decreases as curing progresses. Therefore, the bonding force can be controlled by the amount of the ultraviolet irradiation.

An acrylic resin containing a photopolymerization initiator can be given as an example of the ultraviolet curable resin.

Next, as shown in FIG. 1D, the back surface of the wafer 100 is ground to divide the wafer 100 into a plurality of semiconductor elements 1. More specifically, the back surface of the wafer 100 is ground down to the bottom of the groove 101 described above, and the bottom of the groove 101 is removed to divide the wafer 100 into the plurality of semiconductor elements 1. The back surface of the semiconductor element 1 may be further ground so that the semiconductor element 1 has a prescribed thickness. In this case, known grinding methods and grinding equipment can be used to grind the back surface of the wafer 100, and a detailed description regarding grinding the back surface of the wafer 100 is therefore omitted.

In this way, the plurality of semiconductor elements 1 arranged on the surface protection tape 103 at prescribed intervals can be obtained.

Next, as shown in FIG. 1E, a bonding agent is attached in a film form to the back surface side of the plurality of semiconductor elements 1 divided, and the attached bonding agent is turned into a B-stage state to form an element bonding layer 104.

At this time, this process is accompanied by an element bonding layer 104a being formed on the surface protection tape 103 exposed between semiconductor elements 1.

In addition, this process is also accompanied by an element bonding layer 104b being formed on the side surface of the semiconductor element 1. The element bonding layer may contain an insulative resin as described below, and therefore a short circuit can be suppressed by covering the side surface of the semiconductor element 1 with the element bonding layer 104b.

Examples of the bonding agent include those containing a resin that is a solute and a solvent.

An insulative resin can be given as an example of the resin. A thermosetting resin, a thermoplastic resin, and the like can be given as examples of the insulative resin. In this case, a thermosetting resin such as an epoxy resin, acrylic resin, urethane resin, and silicon resin is preferable from the viewpoints of bonding conditions and heat resistance, and an epoxy resin is more preferable. Examples of the epoxy resin include a bisphenol A epoxy resin, bisphenol F epoxy resin, novolak epoxy resin, and the like. These resins may be used singly, or two or more of them may be mixed for use.

In regard to the solvent, a solvent capable of dissolving the resin that is a solute may be selected as appropriate. For example, γ-butyrolactone (GBL), cyclohexanone, isophorone, and the like can be given. These solvents may be used singly, or two or more of them may be mixed for use. A known hardening accelerator, catalyst, filler, coupling agent, and/or the like may be added as necessary.

Here, if there is unevenness in the surface of the element bonding layer 104 formed, air may get mixed in to generate voids when the semiconductor element 1 is bonded to a matrix such as a substrate and a lead frame. The generation of such voids may cause a defect such as a decrease in the bonding strength. In this regard, by adding an additive having the function of suppressing the surface tension difference (leveling function), the generation of unevenness in the surface of the element bonding layer 104 can be suppressed. As examples of the additive having the function of suppressing the surface tension difference, a silicon-based surface conditioner, acrylic surface conditioner, vinyl surface conditioner, and the like can be given. In this case, a silicon-based surface conditioner is preferably used which is highly effective in equalizing the surface tensions.

Examples of the method for attaching the bonding agent in a film form include a noncontact attaching method such as the ink jet method, spray method, and jet dispense method, a contact attaching method such as the roll coater method and screen printing method, and the like. In this case, a noncontact attaching method such as the ink jet method, spray method, and jet dispense method is preferable which can attach the bonding agent in a film form in a state of not contacting the semiconductor element 1, and the ink jet method is more preferable which can form a thin film with a uniform thickness.

Here, in the case where the ink jet method is used to attach the bonding agent in a film form, the viscosity of the bonding agent at 25° C. is preferably set not more than 0.015 Pa·s in order to suppress the clogging of a discharge nozzle. This viscosity is that in the case of being measured with a Brookfield viscometer (JIS K 7117-2).

In this case, the viscosity of the bonding agent can be controlled by the amount of the resin that is a solute and the amount of the solvent.

For example, in the case where an epoxy resin is used as a solute and γ-butyrolactone (GBL) is used as the solvent, if the ratio of the epoxy resin in the bonding agent is set to about 25 wt %, such a bonding agent as has a viscosity at 25° C. of not more than 0.015 Pa·s can be made. This viscosity is that in the case of being measured with a Brookfield viscometer (RS K 7117-2).

The thickness of the bonding agent when attached in a film form is not specifically limited, but is preferably set not more than 10 μm (micrometers) in view of the vaporization-scattering of the solvent during producing the B-stage state. Furthermore, by setting the thickness of the bonding agent when attached in a film form not more than 10 μm (micrometers), the generation of unevenness in the surface of the element bonding layer 104 can be suppressed as well.

The bonding agent attached in a film form in this way is turned into the B-stage state to form the element bonding layer 104. When the bonding agent is turned into the B-stage state, the bonding agent attached in a film form is heated to vaporize away the solvent.

A heating method such as a heater may be used to heat the bonding agent attached in a film form. For example, a method may be used in which the plurality of semiconductor elements 1 on which the bonding agent is attached in a film form are mounted on a mounting unit having a built-in heater or the like together with the surface protection tape 103, and the bonding agent is heated via the semiconductor elements 1.

The heating temperature (the temperature of the mounting unit) may be set not less than 40° C. and not more than 120° C., for example.

In this case, a proper heating temperature is determined as appropriate based on the composition of the bonding agent, the thickness of the bonding agent when attached in a film form, and the like.

For example, in the case where an epoxy resin is used as a solute of the bonding agent, γ-butyrolactone (GBL) is used as the solvent, the ratio of the epoxy resin in the bonding agent is set to 25 wt %, and the thickness of the bonding agent when attached in a film form is set to about 10 μm (micrometers), the heating temperature (the temperature of the mounting unit) may be set to about 70° C.

Thus, the element bonding layer 104 can be formed on the back surface side of the semiconductor element 1. In the case where it is attempted to make the thickness of the element bonding layer 104 thick, the processes described above may be repeated to form the element bonding layer 104 in a stacked configuration.

Next, as shown in FIG. 1F, a dicing tape 105 is attached to the side opposite to surfaces in which a circuit pattern is formed of the plurality of semiconductor elements 1 on which the element bonding layer 104 is formed (the back surface side of the semiconductor elements 1). The dicing tape 105 is attached so as to cover the entire back surface side of the plurality of semiconductor elements 1 arranged on the surface protection tape 103 at prescribed intervals via a bonding layer 105b (a second bonding layer) that contains an active energy ray curable resin described below (a second active energy ray curable resin).

The laminating method, for example, may be used to attach the dicing tape 105 so as to cover the entire back surface side of the semiconductor elements 1. Then, the side to which the surface protection tape 103 is attached is turned up to facilitate the removal of the surface protection tape 103. Known technology can be applied to the laminating equipment used for the laminating method, the conditions of the laminating, and the like, and a description thereof is therefore omitted.

The dicing tape 105 includes a matrix 105a and the bonding layer 105b provided on the matrix 105a.

The material of the matrix 105a may be appropriately selected based on the method for controlling the bonding force of the bonding layer 105b described below. For example, in the case where the bonding layer 105b is formed of a visible light curable resin as described below, the matrix 105a may be made of a resin or the like capable of transmitting visible light (e.g. with a wavelength of 400 nm (nanometers) to 800 nm (nanometers)). In this case, visible light has a longer wavelength than ultraviolet light described above, and therefore tends to be less easily scattered. Therefore, visible light can be easily transmitted through the matrix 105a, and the matrix 105a may be made of the ultraviolet transmitting resin described above. For example, the matrix 105a may be made of a polyester resin such as polyethylene terephthalate (PET), a polystyrene-based resin, a fluororesin, a polyethylene-based resin, a vinyl resin, or the like.

The bonding layer 105b may be formed of an active energy ray curable resin. The bonding layer 105b formed of an active energy ray curable resin has the properties that it has a prescribed bonding force before being irradiated with an active energy ray having a prescribed wavelength and the bonding force decreases upon irradiation with the active energy ray having a prescribed wavelength in accordance with the irradiation amount.

Here, the wavelength of the applied active energy ray is set different between the bonding layer 105b and the bonding layer 103b described above. In view of this, an example is herein taken up in which the bonding layer 105b is formed of a visible light curable resin.

The visible light curable resin may contain a visible light curable composition and be cured by a polymerization reaction upon visible light irradiation.

In this case, the visible light curable resin has a prescribed bonding force before being irradiated with visible light and the bonding force decreases upon visible light irradiation in accordance with the irradiation amount. That is, the bonding force decreases as curing progresses. Therefore, the bonding force can be controlled by the amount of the visible light irradiation.

The visible light curable resin may contain a thermoplastic resin such as a thermoplastic acrylic resin as a major component, for example.

Next, as shown in FIG. 1G, the surface protection tape 103 is iraddiated with ultraviolet light. That is, the bonding layer 103b is irradiated with ultraviolet light.

Since the matrix 103a is formed of an ultraviolet transmitting resin as described above, the irradiation of ultraviolet light is transmitted through the matrix 103a to reach the bonding layer 103b.

Since the bonding layer 103b is formed of an ultraviolet curable resin, the bonding layer 103b is cured by a polymerization reaction upon the ultraviolet irradiation.

In this case, the ultraviolet curable resin has a prescribed bonding force before being irradiated with the ultraviolet light, and the bonding force decreases upon the ultraviolet irradiation in accordance with the irradiation amount. That is, the bonding force of the bonding layer 103b decreases as curing progresses.

In view of this, the bonding force between the bonding layer 103b and the semiconductor element 1 is controlled to a level weaker than the bonding force between the bonding layer 105b and the element bonding layer 104. In this case, the bonding force between the bonding layer 103b and the semiconductor element 1 is weakened to allow the surface protection tape 103 to be easily removed, and the bonding force between the bonding layer 103b and the element bonding layer 104a is controlled to fall within a prescribed range.

Since the control of the bonding force like this can be made by the amount of the ultraviolet irradiation, the bonding force can be controlled by the intensity, irradiation time, and the like of the ultraviolet light.

Since the bonding layer 105b is formed of a visible light curable resin, the bonding force does not decrease even when the ultraviolet light is applied.

The ultraviolet irradiation may be performed with an ultraviolet irradiation apparatus 200 or the like equipped with an ultraviolet lamp and the like, for example. Known technology can be applied to the ultraviolet irradiation apparatus 200, and a description thereof is therefore omitted.

The amount of the ultraviolet irradiation is illustrated as follows.

For example, in the case where the bonding layer 103b is formed of an ultraviolet curable resin, it is possible to set the thickness of the bonding layer 103b to 10 μm (micrometers), the wavelength of the ultraviolet light irradiation to 365 nm (nanometers), and the required amount of the ultraviolet light to 200 to 400 mJ/cm².

Next, as shown in FIG. 1H, the surface protection tape 103 is removed.

The removal of the surface protection tape 103 can be performed by a method in which the dicing tape 105 is held by a holding unit 201, and an end of the surface protection tape 103 is pulled in the direction of the arrow in the drawing while being held with a vacuum chuck or the like.

When the surface protection tape 103 is removed, the element bonding layer 104a formed on the surface protection tape 103 is separated from the element bonding layer 104b. That is, the element bonding layer 104a formed on the surface protection tape 103 is removed. Consequently, the semiconductor elements 1 connected via the element bonding layers 104a are separated. Known technology can be applied to the removal equipment used for the removal of the surface protection tape 103, the conditions of the removal, and the like, and a description thereof is therefore omitted.

In the embodiment, as described above, ultraviolet irradiation is used to weaken the bonding force between the bonding layer 103b provided in the surface protection tape 103 and the semiconductor element 1 so that the surface protection tape 103 can be easily removed. In this case, since the bonding layer 105b is formed of a visible light curable resin, the bonding force does not decrease even when the ultraviolet light is applied. As a consequence, the surface protection tape 103 can be easily removed, and the possibility can be reduced that the semiconductor element 1 is removed from the dicing tape 105 or the semiconductor element 1 slips out of place during the removal of the surface protection tape 103.

Furthermore, the bonding force between the bonding layer 103b provided in the surface protection tape 103 and the element bonding layer 104a is controlled to fall within a prescribed range during the ultraviolet irradiation.

Thus, the possibility can be reduced that the element bonding layer 104a formed on the surface protection tape 103 remains on the element bonding layer 104b side and is not removed during the removal of the surface protection tape 103.

Next, as shown in FIG. 1I, the dicing tape 105 is irradiated with visible light. More specifically, the bonding layer 105b is irradiated with an active energy ray (visible light) having a wavelength different from the active energy ray (ultraviolet light) illustrated in FIG. 1G.

Since the matrix 105a is formed of a resin capable of transmitting visible light as described above, the irradiation of visible light is transmitted through the matrix 105a to reach the bonding layer 105b.

Furthermore, since the bonding layer 105b is formed of a visible light curable resin, the bonding layer 105b is cured by a polymerization reaction upon the visible light irradiation.

In this case, the visible light curable resin has a prescribed bonding force before being irradiated with the visible light, and the bonding force decreases upon the visible light irradiation in accordance with the irradiation amount. That is, the bonding force of the bonding layer 105b decreases as curing progresses.

In view of this, the bonding force between the bonding layer 105b provided in the dicing tape 105 and the element bonding layer 104 formed on the back surface of the semiconductor element 1 is controlled to allow the semiconductor element 1 to be easily picked up in the die bonding process. That is, the bonding force between the bonding layer 105b provided in the dicing tape 105 and the element bonding layer 104 formed on the back surface of the semiconductor element 1 is weakened to allow the semiconductor element 1 to be easily removed from the dicing tape 105.

The visible light irradiation can be performed with a visible light irradiation apparatus 202 or the like equipped with a visible light lamp and the like, for example. In this case, the visible light irradiation apparatus 202 may be equipped with a visible light filter that transmits visible light. Known technology can be applied to the visible light irradiation apparatus 202, and a description thereof is therefore omitted.

The amount of the visible light irradiation is illustrated as follows.

For example, in the case where the bonding layer 105b is formed of a visible light curable resin, it is possible to set the thickness of the bonding layer 105b to 10 μm (micrometers), the wavelength of the visible light irradiation to 435 nm (nanometers), and the required amount of the light for curing to 250 to 1500 mJ/cm².

The processes illustrated in FIG. 1G to FIG. 1I may be performed in the dicing process or the die bonding process, or between the dicing process and the die bonding process.

Although the case has been illustrated where the bonding layer 103b is formed of an ultraviolet curable resin and irradiated with ultraviolet light and the bonding layer 105b is formed of a visible light curable resin and irradiated with visible light, the embodiment is not limited thereto. For example, the bonding layer 103b may be formed of a visible light curable resin and irradiated with visible light, and the bonding layer 105b may be formed of an ultraviolet curable resin and irradiated with ultraviolet light.

Furthermore, although the case has been illustrated where ultraviolet light (e.g. with a wavelength of 400 nm (nanometers) or less) and visible light (e.g. with a wavelength of 400 nm (nanometers) to 800 nm (nanometers)) are used as active energy rays, an electron beam (e.g. with a wavelength of 0.0037 nm (nanometers) or less) or infrared light (with a wavelength of 800 nm (nanometers) or more) may be used. In the case of using an electron beam or infrared light, an active energy ray curable resin that is cured by being irradiated with the electron beam or infrared light may be used as appropriate.

Moreover, although the case has been illustrated where the bonding force of the bonding layer 105b provided in the dicing tape 105 is controlled after the bonding force of the bonding layer 103b provided in the surface protection tape 103 is controlled, the embodiment is not limited thereto. In those cases where the bonding force of the bonding layer 105b after control is sufficiently stronger than the bonding force of the bonding layer 103b after control, it is possible to control the bonding force of the bonding layer 103b after controlling the bonding force of the bonding layer 105b, or to control the boding force of the bonding layer 103b and the bonding force of the bonding layer 105b almost simultaneously.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A method for manufacturing a semiconductor device comprising:
forming a groove with a depth shallower than a thickness of a wafer from a side of a surface of the wafer in which a circuit pattern is formed;
attaching a surface protection tape to the side of the surface of the wafer in which the circuit pattern is formed via a first bonding layer provided in the surface protection tape and containing a first active energy ray curable resin;
grinding a surface of the wafer on a side opposite to the surface in which the circuit pattern is formed to divide the wafer into a plurality of semiconductor elements;
forming an element bonding layer by attaching a bonding agent to the plurality of semiconductor elements divided and turning the attached bonding agent into a B-stage state;
attaching a dicing tape to a side opposite to surfaces of the plurality of semiconductor elements in which a circuit pattern is formed on which the element bonding layer is formed via a second bonding layer provided in the dicing tape and containing a second active energy ray curable resin;
irradiating the first bonding layer with a first active energy ray;
removing the surface protection tape; and
irradiating the second bonding layer with a second active energy ray having a wavelength different from the first active energy ray.

2. The method according to claim 1, wherein a bonding force between the first bonding layer and the semiconductor element is controlled to a level weaker than a bonding force between the second bonding layer and the element bonding layer in the irradiation of the first active energy ray.

3. The method according to claim 1, wherein the first active energy ray is one selected from the group consisting of an electron beam, ultraviolet light, visible light, and infrared light.

4. The method according to claim 1, wherein the second active energy ray is one selected from the group consisting of an electron beam, ultraviolet light, visible light, and infrared light.

5. The method according to claim 1, wherein the first bonding layer has a prescribed bonding force before being irradiated with an active energy ray having a prescribed wavelength and a bonding force decreases upon irradiation of an active energy ray having a prescribed wavelength in accordance with irradiation amount.

6. The method according to claim 1, wherein the second bonding layer has a prescribed bonding force before being irradiated with an active energy ray having a prescribed wavelength, and a bonding force decreases upon irradiation of an active energy ray having a prescribed wavelength in accordance with irradiation amount.

7. The method according to claim 1, wherein
the first active energy ray curable resin is an ultraviolet curable resin,
the first active energy ray is ultraviolet light,
the second active energy ray curable resin is a visible light curable resin, and
the second active energy ray is visible light.

8. The method according to claim 7, wherein a required amount of the ultraviolet light is not less than 200 mJ/cm² and not more than 400 mJ/cm² and a required amount of the visible light is not less than 250 mJ/cm² and not more than 1500 mJ/cm².

9. The method according to claim 1, wherein
the first active energy ray curable resin is a visible light curable resin,
the first active energy ray is visible light,
the second active energy ray curable resin is an ultraviolet curable resin, and
the second active energy ray is ultraviolet light.

10. The method according to claim 9, wherein a required amount of the visible light is not less than 250 mJ/cm² and not more than 1500 mJ/cm², and a required amount of the ultraviolet light is not less than 200 mJ/cm² and not more than 400 mJ/cm².

11. The method according to claim 1, wherein the surface protection tape transmits ultraviolet light with a wavelength of not more than 400 nanometers, and the dicing tape transmits visible light with a wavelength of more than 400 nanometers and not more than 800 nanometers.

12. The method according to claim 1, wherein the dicing tape transmits ultraviolet light with a wavelength of not more than 400 nanometers, and the surface protection tape transmits visible light with a wavelength of more than 400 nanometers and not more than 800 nanometers.

13. The method according to claim 1, wherein the surface protection tape is one selected from the group consisting of a polyester resin, polystyrene-based resin, fluororesin, polyethylene-based resin, and vinyl resin.

14. The method according to claim 1, wherein the dicing tape is one selected from the group consisting of a polyester resin, polystyrene-based resin, fluororesin, polyethylene-based resin, and vinyl resin.

15. The method according to claim 1, wherein the bonding agent contains an additive having a function of suppressing a surface tension difference.

16. The method according to claim 15, wherein the additive having the function of suppressing the surface tension difference is one selected from the group consisting of a silicon-based surface conditioner, acrylic surface conditioner, and vinyl surface conditioner.

17. The method according to claim 1, wherein the bonding agent is caused to have a viscosity at 25° C. of not more than 0.015 Pa·s.

18. The method according to claim 1, wherein a thickness of the bonding agent when attached is made not more than 10 micrometers in the forming the element bonding layer.

19. The method according to claim 1, wherein the element bonding layer is formed on a side surface of the semiconductor element in the forming the element bonding layer.

20. The method according to claim 1, wherein the attached bonding agent is heated at not lower than 40° C. and not higher than 120° C. into a B-stage state in the forming the element bonding layer.
